(19) United States
(12) Patent Application Publication
(10) Pub. No.: US 2013/0112241 A1
(43) Pub. Date: May 9, 2013

(54) PHOTOVOLTAIC MODULE COMPRISING AN ELECTRICAL CONNECTION AND HAVING AN OPTICAL FUNCTION

(71) Applicants: Eric Gerritsen, Bernin (FR); Philippe Thony, Entre-Deux-Guiers (FR)

(72) Inventors: Eric Gerritsen, Bernin (FR); Philippe Thony, Entre-Deux-Guiers (FR)

(73) Assignee: Commissariat A L'Energie Atomique Et Aux Energies Alternatives, Paris (FR)

(21) Appl. No.: 13/511,954

(22) PCT Filed: Oct. 28, 2010
(86) PCT No.: PCT/FR10/52315

§ 371 Date: May 25, 2012

(30) Foreign Application Priority Data
Dec. 14, 2009 (FR) 0958916

(51) Int. Cl. H01L 31/05

(52) U.S. Cl. CPC H01L 31/0508
USPC 136/246

(57) ABSTRACT

The invention relates to a photovoltaic module comprising a plurality of photovoltaic cells electrically connected in series via connection means comprising electrical conductors. Each connection means comprises an optical device having a reflection-diffractive or transmission-diffractive optical behaviour, and each connection means consists of a sheet formed from a material transparent to incident rays containing at least one network of electrical conductor wires.

### TECHNICAL FIELD

The invention relates to a photovoltaic module that can convert photons from incident light rays to electrical energy. It relates more specifically to the connections between photovoltaic cells of one and the same module.

### BACKGROUND OF THE INVENTION

Generally speaking a photovoltaic module is formed by a plurality of photovoltaic cells 2 each having a front face 20 and a rear face 21. These photovoltaic cells 2 may be monofacial, i.e. having only one active face, or bifacial, i.e. having an active front face and an active rear face, each of the active faces being able to capture and convert photons from incident light rays falling on these active faces to electrical energy. These photovoltaic cells 2 are arranged to have a gap separating them from one another, and are connected to one another electrically in series, via connection means 3 running from the front face 20 of one cell to the rear face 21 of the adjacent cell, as shown in FIG. 1.

The electrical connection between the photovoltaic cells is not optimum because of the deformation sustained by these connection means. Such an arrangement of these connection means requires the provision of a significant gap separating the cells, thereby reducing the active surface of the resulting panel. To this end, a proposal has been made to implement planar connections, which however still screen some of the front face of the cells. Incidentally, a gap separating said cells is still required.

In this context, the purpose of this invention is to propose another photovoltaic module that is free from this previously mentioned limitation. The specific purpose of the invention is to propose a photovoltaic module which offers improved electrical efficiency for a given device or module surface.

### DISCLOSURE OF THE INVENTION

The invention relates to this end to a photovoltaic module comprising a plurality of photovoltaic cells electrically connected in series via connection means comprising electrical conductors. According to the invention, each connection means comprises an optical device having a reflection-diffractive or transmission-diffractive optical behaviour. Additionally, according to the invention, each connection means consists of a sheet formed from a material that is transparent to incident rays containing at least one network of electrical conductor wires.

In other words, the invention comprises using the electrical connections between the cells as an optical device. The rays redirected by the optical devices may in particular be used to increase the electrical efficiency of the cells. Therefore, whereas the norm is for the connections to take up some of the active surface of the cells, surface which is then lost in terms of efficiency, the invention unusually opts to increase this “lost” surface while conferring thereupon an optical function in order to return photons to the cells thereby compensating for the loss of active surface.

Additionally, the optical device may have various optical functions simultaneously, such as transparency and diffraction for example.

To advantage, the front face of each cell is connected to the front face of an adjacent cell, and the rear face of said cell is connected to the rear face of another adjacent cell.

The electrical connection is thus planar, which facilitates the methods of manufacture.

Preferably, each connection means additionally has an optical behaviour suitable for letting through all or part of the incident light photons. For example, the connection means may be transparent for some wavelengths.

According to one embodiment of the invention, the network of conductor wires has a design that can send the diffracted light rays in a direction perpendicular to the direction of flow of the electric current between two interconnected adjacent photovoltaic cells.

Each cell may have an active front face and an active rear face, and the photovoltaic module may further comprise a rear plate placed opposite the rear faces of the cells, said rear plate having reflecting zones that can send the incident photons towards the rear faces of the cells.

For example, the rear plate may additionally have zones that can let through all or part of the light rays. The rear plate may be formed from a transparent material.

### BRIEF DESCRIPTION OF THE DRAWINGS

Other characteristics and advantages of the invention will become clearer from the description given thereof hereinafter, for information purposes and non-restrictively, with reference to the appended drawings, wherein:

FIG. 1 is a partial diagrammatic view in cross-section of a photovoltaic cell from the prior art;

FIG. 2 is a partial diagrammatic plane view of a photovoltaic module comprising electrical connection means having a design according to one embodiment of the invention;

FIG. 3 is a partial diagrammatic plane view of a photovoltaic module comprising electrical connection means having another design according to another embodiment of the invention;

FIG. 4 is a diagrammatic view of another design of the electrical connection means according to another embodiment of the invention;

FIG. 5 is a diagrammatic view of another design of the electrical connection means according to another embodiment of the invention;

FIG. 6 is a partial diagrammatic view in cross-section of a photovoltaic module according to another embodiment of the invention;

FIG. 7 is a partial diagrammatic plane view of the photovoltaic module in FIG. 6;

FIG. 8 is a partial diagrammatic view in cross-section of the photovoltaic module comprising a rear plate provided with reflective means according to one embodiment of the invention; and

FIG. 9 is a partial diagrammatic view in cross-section of the photovoltaic module comprising a rear plate provided with reflective means according to another embodiment of the invention.

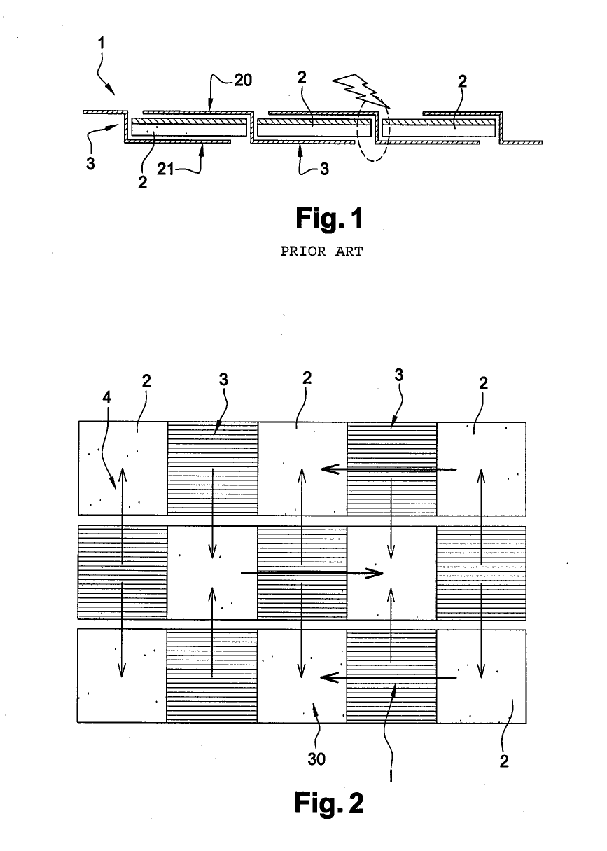

### DETAILED DISCLOSURE OF EMBODIMENTS OF THE INVENTION

According to the invention, a photovoltaic module 1 comprises a plurality of photovoltaic cells 2 electrically connected in series via connection means 3 each having an optical behaviour. Each connection means 3 consists in this instance of a sheet formed from a material that is transparent or semi-transparent relative to incident rays, and containing conductor wires 30, of nanometric dimension for example.

This optical behaviour may be of the reflection-diffractive or transmission-diffractive type.

In one embodiment of the invention, and with reference to FIG. 2, the conductor wires 30 of a connection means 3 are arranged to be spaced apart from one another, parallel to each other and parallel to a direction of flow I of an electric current. Because of the gap separating the conductor wires, the electrical connection means 3 behaves like a diffraction network for the incident light rays. The diffracted rays 4 are sent in a direction perpendicular to the conductor wires or to the direction of flow I of the electric current. In this embodiment, the ratio of the surface occupied by the cells to that of the connection means may be equal to 1.

Such a structure may be formed by etching in transparent polymer sheets coated with a thin film of a conductor metal such as aluminium or copper or silver. The conductor wires may also be obtained by printing on polymer sheets using a conductive ink.

According to another technical solution, an electrically conductive material is employed, and an optical property is conferred thereupon by structuring the surface thereof. Thus, depending on the form, spacing, and repetition of the designs, the surface of the material becomes a diffraction network.

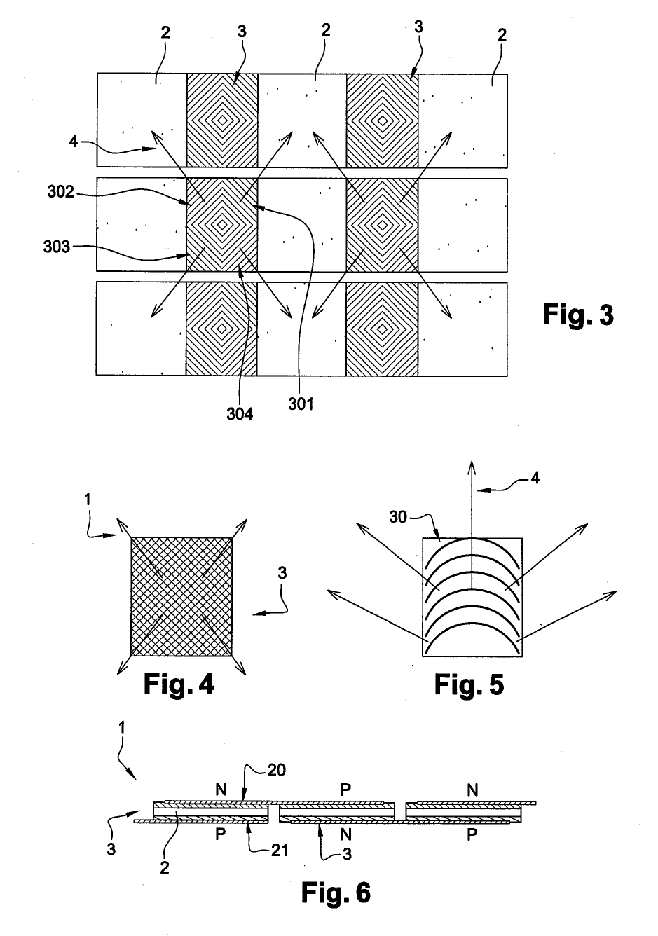

According to another embodiment of the invention and with reference to FIG. 3, the conductor wires 30 of a connection means 3 are arranged in a so-called fishbone pattern. In other words, the connection means comprises four groups of conductor wires:
a first group 301 of conductor wires arranged parallel to each other, and oriented at an angle of 45° relative to the direction of flow I of the electric current;
a second group 302 of conductor wires arranged symmetrically to the first group 301 relative to a first axis perpendicular to the direction of flow I of the electric current, said axis being parallel to the faces of the cells;
a third group 303 of conductor wires arranged symmetrically to the second group 302 relative to a second axis perpendicular to said first axis, said first and second axes being co-planar;
and lastly a fourth group 304 of conductor wires symmetrical to the first group 301 relative to the second axis.

In this embodiment, each of the groups 301, 302, 303, 304 behaves like a diffraction network and the diffracted rays are sent in directions substantially perpendicular to the conductor wires. This pattern confers greater flexibility with regard to the relative arrangement of the cells, as well as to the form thereof.

According to another embodiment of the invention and with reference to FIG. 4, the conductor wires of a connection means may be arranged so as to form grids, which has the same advantage as mentioned above, and which thereby optimises electrical conduction.

According to another embodiment of the invention and with reference to FIG. 5, the conductor wires of a connection means may form elliptical or circular lines. This pattern thereby improves the flexibility of the arrangement.

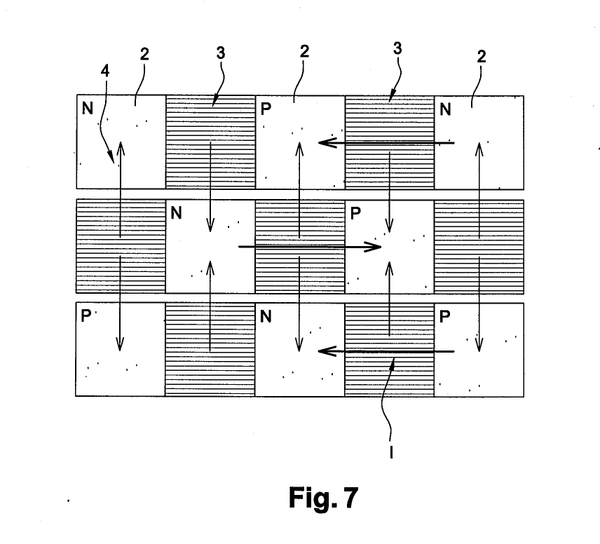

According to another embodiment of the invention and with reference to FIGS. 6 and 7, the cells are bifacial. They are formed in particular from layers of silicon for example, and have a p-doped active face and another n-doped active face. These cells are connected in series via the connection means 3 used in the embodiment in FIG. 2 and are arranged so that the p-type front face of a cell is co-planar with the n-type front face of an adjacent cell. Additionally, the front face of each cell is connected to the front face of an adjacent cell of opposite doping, and the rear face of said cell is connected to the rear face of another adjacent cell, here too, of opposite doping.

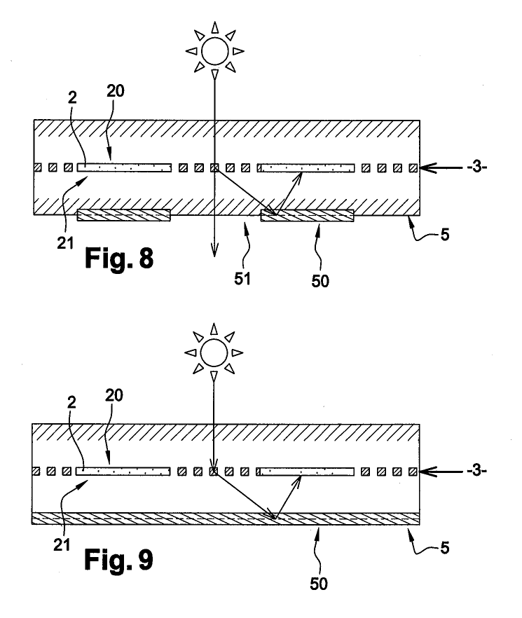

Furthermore, in order to increase the electrical efficiency of the photovoltaic module, each connection means 3 may additionally have an optical behaviour suitable for letting through all or part of the incident light photons, as shown in FIGS. 8 and 9. Additionally, the photovoltaic module may comprise a rear plate 5 placed opposite the rear faces 21 of the cells, said rear plate being provided with reflecting zones 50 that can send back the incident photons falling thereupon towards the rear faces 21 of the cells. As shown in FIG. 8, it is also possible to provide transparent zones 51 on the rear plate 5 in order to let through the natural light in order to illuminate a room.

Another alternative may also comprise providing the rear plate with a reflective device such as a mirror, or a refractive device such as a prism or lens, or else a device such as a concentrator.

It is clear from what has been said above that the originality of the invention lies in the fact that the electrical connection means between the photovoltaic cells have an optical behaviour in relation to the incident rays. These connection means may be transparent so as to let through all or part of the light rays which may then be used to increase the electrical efficiency of the photovoltaic cells through the use in particular of reflective means such as mirrors placed on the rear plate of the photovoltaic module in order to send the photons back towards the rear faces of the cells. These means may also be of the diffractive type, i.e. the light rays have a modified trajectory.

By increasing the surface between the cells and by making use of the rear face of the bifacial cells, it is possible to increase electrical efficiency while reducing the surface of the cells, and therefore the manufacturing cost.

Furthermore, by redirecting some light rays such as infrared rays outwards from the photovoltaic module, it is possible to cool the cells.

1. A photovoltaic module comprising a plurality of photovoltaic cells electrically connected in series via connection means comprising electrical conductors, wherein each connection means comprises an optical device having a reflection-diffractive or transmission-diffractive optical behaviour, and each connection means, being of a planar type, consists of a sheet formed from a material that is transparent to incident rays containing at least one network of electrical conductor wires.

2. The photovoltaic module as claimed in claim 1, wherein the optical device has various optical functions simultaneously, and in particular transparency and diffraction.

3. The photovoltaic module as claimed in claim 1, wherein the front face of each photovoltaic cell is connected to the front face of an adjacent photovoltaic cell, and the rear face of said cell is connected to the rear face of another adjacent cell.

4. The photovoltaic module as claimed in claim 1, wherein each connection means has at least one optical behaviour suitable for letting through all or part of the incident light photons.

5. The photovoltaic module as claimed in claim 1, wherein the network of electrical conductor wires has a design that can send the diffracted light rays in a direction perpendicular to the direction of flow of the electric current between two interconnected adjacent photovoltaic cells.

6. The photovoltaic module as claimed in claim 1, wherein each connection means consists of an electrically conductive material structured so as to produce an optical diffraction network.

7. The photovoltaic module as claimed in claim 1, wherein each photovoltaic cell has an active front face and an active rear face, and in that the photovoltaic module further comprises a rear plate placed opposite the rear faces of the cells, said rear plate having reflecting zones that can send the incident photons towards the rear faces of the cells.

8. The photovoltaic module as claimed in claim 7, wherein the rear plate additionally has transparent zones that can let through incident light rays.
